(19) United States
(12) Patent Application Publication
(10) Pub. No.: US 2006/0255695 A1
(43) Pub. Date: Nov. 16, 2006

(54) Piezo actuator

(76) Inventor: Axel Endriss, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 10/550,932

(22) PCT Filed: Aug. 4, 2004
(86) PCT No.: PCT/DE04/01742

§ 371 Date: Sep. 28, 2005

(30) Foreign Application Priority Data
Oct. 1, 2003 (DE) 10345730.5

(51) Int. Cl. H01L 41/083

(52) U.S. Cl. 310/366

(57) ABSTRACT

A piezoelectric actuator is provided with a multilayer construction of piezoelectric layers perpendicular to the action direction, with inner electrodes located between the piezoelectric layers, which can be subjected to an electrical voltage via outer electrodes. At further piezoelectric layers with inner electrodes, an electrical sensor signal that is proportional to the actuation of the piezoelectric actuator can be picked up via further outer electrodes. The piezoelectric layers for the actuator part and the piezoelectric layers for the at least one sensor part are integrated in one component as a piezoelectric actuator, in such a way that individual piezoelectric layers for the sensor part are located at predetermined spacings or also side by side between the piezoelectric layers for the actuator part.

### PRIOR ART

The invention relates to a piezoelectric actuator, for instance for actuating a mechanical component, and to a sensor mechanically coupled with the piezoelectric actuator, as generically defined by the preamble to the main claim.

It is widely known that by using what is known as the piezoelectric effect, a piezoelectric element can be constructed from a material having a suitable crystal structure. If an external electrical voltage is applied to these piezoelectric and electrostrictive ceramics, a mechanical reaction of the piezoelectric element ensues, which as a function of the crystal structure and of the regions to which the electrical voltage is applied represents a pressure or tension in a predeterminable direction.

Because of the extremely fast and precisely regulatable stroke effect, such piezoelectric actuators can be used to make final control elements, for instance for driving switching valves in fuel injection systems in motor vehicles. The voltage- or charge-controlled deflection of this piezoelectric actuator is utilized to position a control valve, which in turn regulates the stroke of a nozzle needle.

Since the required electrical field intensities for actuating the piezoelectric actuator are in the range of several kV/mm, and as a rule only moderate electrical voltages are wanted for triggering, the construction of this piezoelectric actuator in multiple layers of metallized piezoelectric ceramics stacked on one another produces a so-called multilayer actuator. To that end, there are inner electrodes between each of the layers, the inner electrodes being applied for instance by a printing process, and there are also outer electrodes by way of which the electrical voltage is applied. One typical method for producing such layers is sheet extrusion. The individual layers are metallized for producing the inner electrodes and are stacked on one another; the piezoelectric effect then develops between two layers having inner electrodes of different polarity.

The actual piezoelectric element itself can be used either actively as a piezoelectric actuator, as described above, or passively as a sensor, at which the voltage which occurs when the piezoelectric element is deformed by a mechanical action is picked up.

One such arrangement is described in German Patent Disclosure DE 199 60 971 A1, for example. The voltage signal that can be picked up is, as a pressure sensor, proportional to the force exerted or, as a travel sensor, proportional to the incident deformation. To adjust the change in length of a piezoelectric actuator in a regulated way, this change must be detected, which until now has required a separate component as the sensor element. For that purpose, a strain gauge, for instance glued to the piezoelectric actuator, or an inductive travel pickup, or as described in the prior art cited above, a further piezoelectric sensor may be employed.

### ADVANTAGES OF THE INVENTION

The piezoelectric actuator described at the outset is constructed, as noted, with a multilayer construction of piezoelectric layers and, in a piezoelectrically active region, with inner electrodes located between the layers, and is provided with contacting in alternation, from one layer to another, of the inner electrodes, for subjection to an electrical voltage. For forming a sensor part, further piezoelectric layers are present, with inner electrodes at which an electrical sensor signal proportional to the actuation of the piezoelectric actuator can be picked up via further outer electrodes. According to the invention, the piezoelectric layers for the actuator part and the piezoelectric layers for the at least one sensor part are advantageously integrated in one component in such a way that individual piezoelectric layers for the sensor part are located at predetermined spacings between the piezoelectric layers for the actuator part.

It is thus advantageously attained that the active piezoelectric element, as a piezoelectric actuator, and the passive piezoelectric element, as a sensor, are united in one component. Both functions, namely generating travel and/or force and measuring travel and/or force, may be made use of simultaneously, independently of one another. It is advantageous in this respect primarily that no further additional component is needed as a sensor, which has advantages above all in terms of cost and installation space.

Moreover, the integrated embodiment makes the assembly of the piezoelectric actuator simpler, since the sensor and the actuator are parts of one and the same component and thus a problematic specific assembly is dispensed with, as are other components that might be needed for the purpose, such as a polished fit in the case of a load cell.

Such an actuator-sensor element according to the invention offers advantages particularly wherever high distance precision, for instance in the micrometer and sub-micrometer range, is needed, on the one hand, and on the other, where for reasons of space no further components can be accommodated.

Especially advantageously, with the invention, the injection of fuel can be controlled by means of a direct valve needle control for use in a fuel injection system in a motor vehicle, and even valve needle regulation can be implemented here.

In the exemplary embodiments of the invention described below, a piezoelectric actuator with a piezoelectric sensor can advantageously be combined in one component by stacking individual piezoelectric elements on one another and then triggering them (actuator) or reading them out (sensor) separately in accordance with their function. Piezoelectric layers mechanically connected in series are to that end connected electrically parallel.

Depending on the application, there may be a large number of active piezoelectric layers of the actuator part along with a comparatively small number of passive piezoelectric layers of the sensor part, or vice versa. Since the absolute amounts of the elongation in the piezoelectric effect are low but the attendant charge quantities are high, in some preferred exemplary embodiments there may be many active elements and only a few passive elements. The stacking can be appropriately done in such a way that after a certain number, such as 20, of active piezoelectric layers, a single sensor element, comprising at least one passive layer, is built in and contacted. The sensor element may furthermore be subdivided into a plurality of individual segments, located side by side, as a result of which the sensor signal can be picked up multiple times, increasing the security against failure.

Whether the stack construction involves individual piezoelectric layers glued together or individual layers stacked in the so-called green state and then sintered together to make a ceramic body (cofiring method) does not matter for the advantageous function of the invention.

It is advantageous if, when the cross section of the piezoelectric actuator is rectangular, the electrically positive and negative outer electrodes of the actuator part and of the sensor parts are mounted on diametrically opposite sides of the piezoelectric actuator but extend to the outside offset by 90° from one another. However, it is also possible for the outer electrodes of both the actuator part and the sensor part to be located together on two diametrically opposite sides of the piezoelectric actuator.

In another advantageous exemplary embodiment, the inner electrodes of the sensor parts are guided into the corner region of the piezoelectric actuator, where they are each contacted with the outer electrodes. When there are a plurality of sensor parts, the various inner electrodes may advantageously be contacted in alternation with outer electrodes on different flanks of the edge region.

If the component includes a plurality of sensor elements mechanically connected parallel to one another in the action direction, they can be connected electrically parallel to one another by providing that the various inner electrodes of the same polarity are contacted in common on the outside, as a result of which the sensitivity of the sensor is improved.

In another advantageous embodiment, when there are a plurality of sensor parts that are contacted with outer electrodes, the various inner electrodes of the sensor parts having the same polarity are contacted one after the other in the action direction of the piezoelectric actuator, on one side of the piezoelectric actuator.

### DRAWING

Advantageous exemplary embodiments of a piezoelectric actuator of the invention, with integrated sensors, are described in conjunction with the drawing. Shown are:

FIG. 1, a section through a piezoelectric actuator having a multilayer construction of layers of piezoelectric ceramic and inner electrodes between them, for both an actuator part and a sensor part;

FIG. 2, a section corresponding to FIG. 1, but in which the piezoelectric actuator is subdivided into a plurality of active actuator parts and passive sensor parts;

FIG. 3, a cross section through the piezoelectric actuator of FIG. 1;

FIG. 4, a cross section through a piezoelectric actuator having two sensor piezoelectric layers located side by side;

FIG. 5, a cross section through a piezoelectric actuator having three sensor piezoelectric layers located side by side;

FIG. 6 and FIG. 7, a cross section and a perspective view, respectively, of a piezoelectric actuator with one actuator part and one sensor part, which are each contacted on the same side of the piezoelectric actuator;

FIG. 8 and FIG. 9, a further variant of the exemplary embodiment of FIGS. 6 and 7;

FIG. 10 and FIG. 11, a cross section and a perspective view, respectively, of a piezoelectric actuator with smaller inner electrodes, contacted at the corners, for the sensor part.

### DESCRIPTION OF THE EXEMPLARY EMBODIMENTS

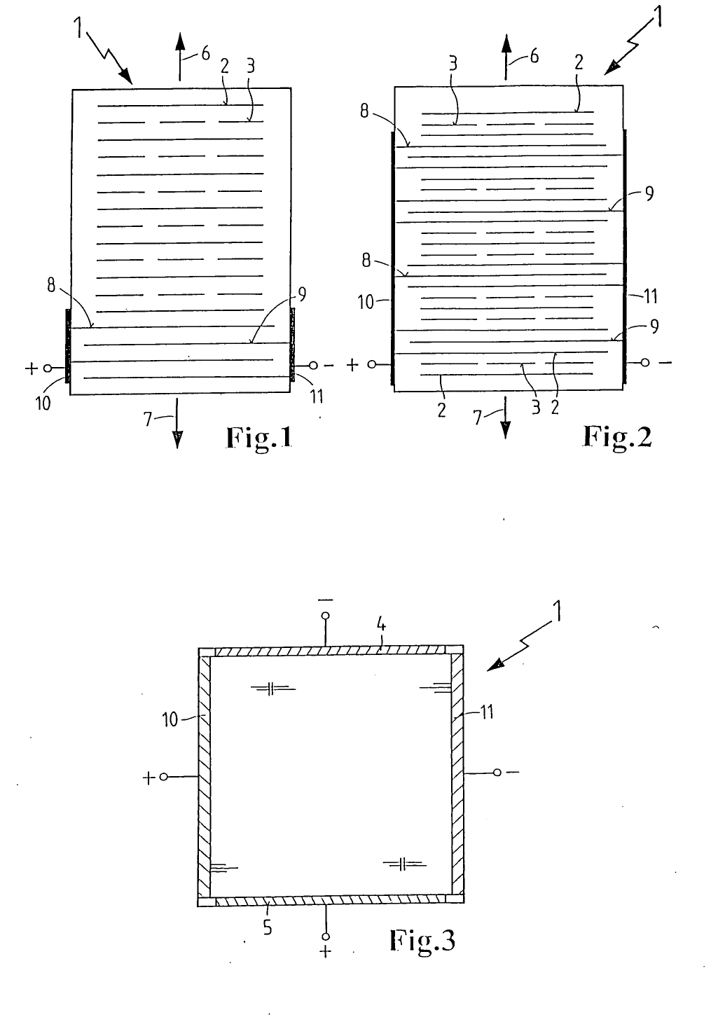

In FIG. 1, a piezoelectric actuator 1 is shown, which is constructed in a manner known per se of piezoelectric layers of a ceramic material, such as so-called green sheets, having a suitable crystal structure, so that by utilizing the so-called piezoelectric effect when an external electrical direct voltage is applied to inner electrodes 2 and 3, via outer electrodes 4 and 5 not shown here but visible in FIG. 3, a mechanical reaction of the piezoelectric actuator 1 in the action direction 6 or 7, as applicable, takes place. The piezoelectric layers with the inner electrodes 2 and 3 are distributed here over the entire construction of the piezoelectric actuator 1 in the action direction 6 or 7 as applicable and are baked together in a manner known from the prior art, such as by sintering.

A longitudinal section through the piezoelectric actuator 1 of FIG. 1 thus shows a stacked construction in which the active piezoelectric layers are contacted with the various inner electrodes 2 and 3 perpendicular to the plane of the drawing, in alternation above and then below, on the outside of the piezoelectric actuator 1. Passive piezoelectric layers with inner electrodes 8 and 9 are also located between these active piezoelectric layers, and these sensor piezoelectric layers, offset by 90°, are guided to the left to an outer electrode 10 and to the right to an outer electrode 11, where they are contacted. The 90°-offset arrangement of the sensor part and actuator part is not necessarily required.

The construction for the case shown in FIG. 2, in which a plurality of actuator parts and sensor parts are mechanically connected in series and electrically parallel, is done analogously.

This construction can also be seen from the cross-sectional view of FIG. 3, from which it can be seen that the outer electrodes 4 and 5, for activating the piezoelectric actuator 1, are mounted on the two diametrically opposite sides, in this view above and below, of the piezoelectric actuator 1, and the outer electrodes 10 and 11 for the sensor part are mounted diametrically opposite to the right and left on the piezoelectric actuator 1. Further modifications with segmented sensor parts and alternatives for contacting the inner electrodes to the outside by means of a special buried disposition of the inner electrodes 2 and 3 on the one hand and 8 and 9 on the other in the piezoelectric actuator 1 will be described below in terms of the following exemplary embodiments.

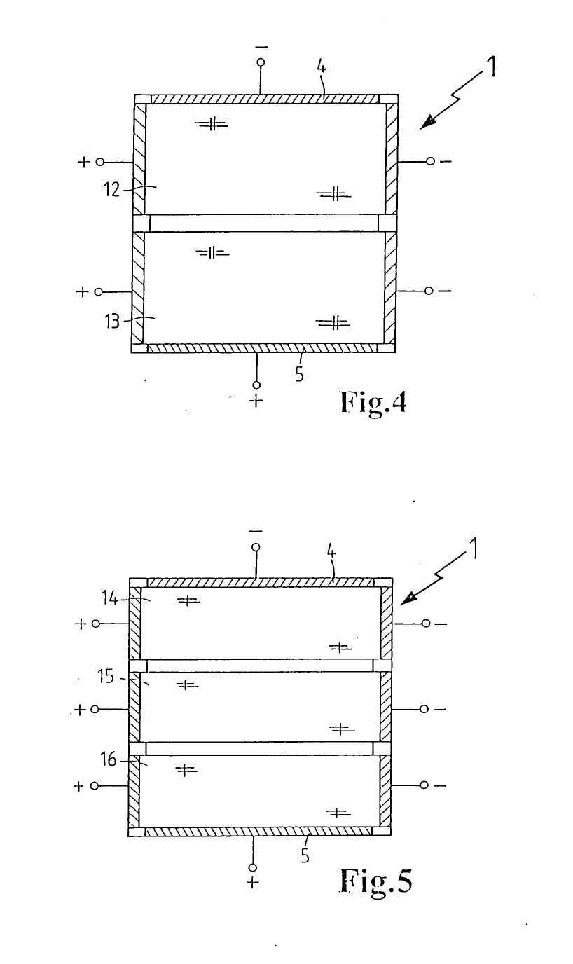

One possible variant in terms of the design of the sensor part is shown in FIG. 4; here, in a modification from the previous exemplary embodiment, two sensor layers each with corresponding sensor piezoelectric layers 12 and 13 are accommodated side by side in one plane and therefore, to enhance the reliability of measurement, the sensor signal can be picked up twice, instead of only once, at corresponding outer electrodes. By means of a suitable modification of the design of the piezoelectric actuator 1 for the sensor inner electrodes, these inner electrodes can be subdivided still further, and thus even a triple segmentation with sensor piezoelectric layers 14, 15 and 16 as in FIG. 5 can be produced in a simple way.

By means of such a segmentation of the sensor inner electrodes, or a sequential subdivision in the longitudinal direction as well, more than only a single sensor signal can be picked up. Hence the possibility fundamentally exists of either using them separately or connecting them parallel for the sake of doubling or multiplying the sensor signal.

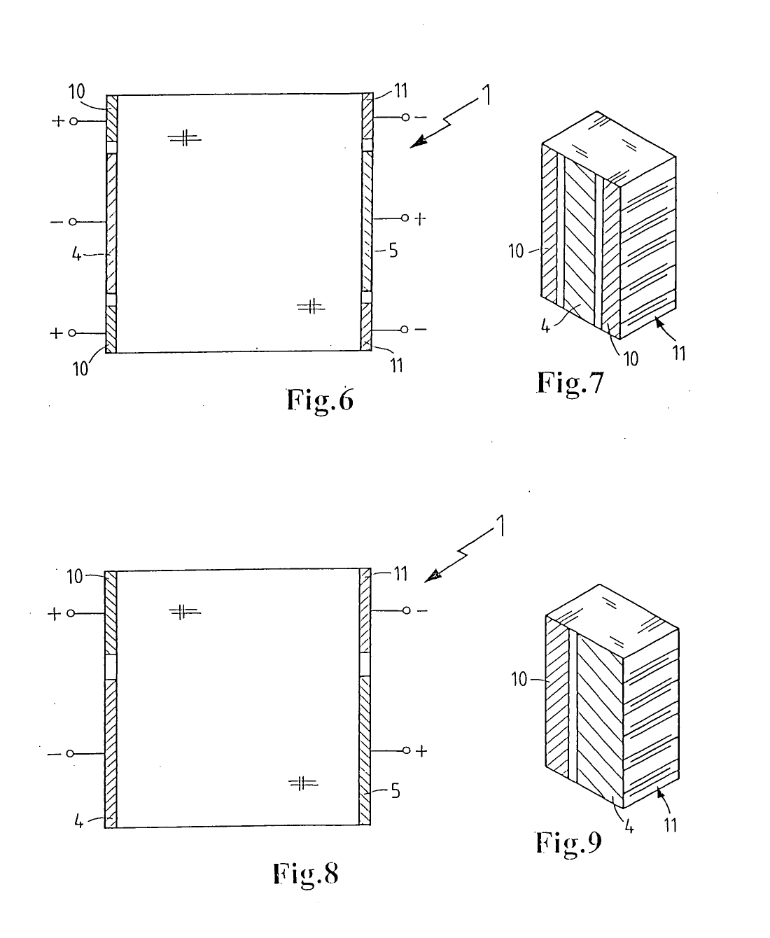

Further variants with possibilities for contacting the actuator part and sensor part, with both on the same side of the piezoelectric actuator 1, are shown in two further exemplary embodiments shown in FIGS. 6 and 7 on the one hand and FIGS. 8 and 9 on the other; FIGS. 7 and 9 each show a perspective view of the exemplary embodiment of FIGS. 6 and 8, respectively. Since the functions of the components are essentially the same as those in FIGS. 1 through 3, analogous reference numerals are chosen here. It is also possible here for the sensor part to be segmented into a plurality of parts located side by side, as shown in FIGS. 4 and 5.

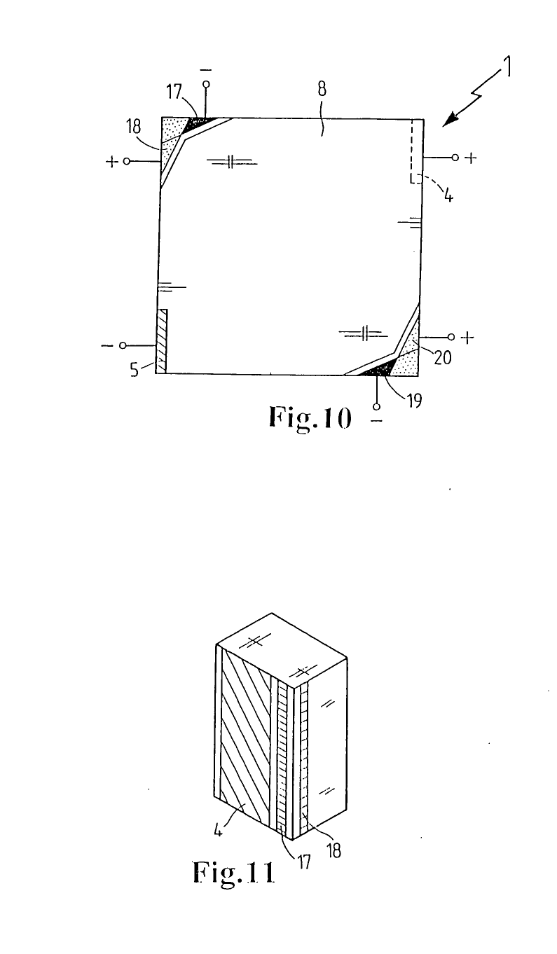

In FIG. 10 and in associated FIG. 11, an exemplary embodiment is shown with which a further advantageous combination of the actuator part and sensor part is made possible, in which the inner electrode design is modified in such a way that in each piezoelectric layer, there is one actuator piezoelectric layer and one or more sensor piezoelectric layers. The smaller capacitor area 17, 18 or 19, 20, of the sensor inner electrodes of FIGS. 10 and 11 is opposed by a larger number of sensor piezoelectric layers, and as a result, an acceptable sensor output signal can be attained here as well. In this variant, it is especially advantageous that a failure of a few individual layers, for instance from partial detachment of the external contacting means, has only a slight impact. Especially if there is a double embodiment of the sensor part, this variant has increased safety.

1-7. (canceled)

8. A piezoelectric actuator, comprising
an actuator part including multilayer construction of piezoelectric layers perpendicular to the action direction, with inner electrodes which are located between the piezoelectric layers and which can be acted upon by an electrical actuator voltage for actuating the piezoelectric actuator part via outer electrodes, and
at least one sensor part including further piezoelectric layers with inner electrodes at which an electrical sensor signal proportional to the actuation of the piezoelectric actuator can be picked up via further outer electrodes,
the piezoelectric layers for the actuator part and the piezoelectric layers for the at least one sensor part being integrated in one component as a piezoelectric actuator in such a way that individual sensor piezoelectric layers are located at predeterminable spacings or locations between the piezoelectric layers for the actuator part.

9. The piezoelectric actuator according to claim 8, wherein
when the cross section of the piezoelectric actuator is rectangular, electrically positive and negative outer electrodes of the actuator part, and electrically positive and negative outer electrodes of the sensor part are each mounted on diametrically opposite sides of the piezoelectric actuator.

10. The piezoelectric actuator according to claim 9, wherein
in the case of a plurality of sensor parts each individually contacted by outer electrodes, the various sensor piezoelectric layers of the sensor parts are located side by side in a plane transverse to the action direction; and
in these sensor parts, the inner electrodes having the same polarity in the action direction of the piezoelectric actuator are contacted parallel to one another, on one side of the piezoelectric actuator, by outer electrodes.

11. The piezoelectric actuator according to claim 9, wherein
both the outer electrodes of the actuator part and the outer electrodes of the at least one sensor part are located side by side on two diametrically opposite sides of the piezoelectric actuator.

12. The piezoelectric actuator according to claim 10, wherein
both the outer electrodes of the actuator part and the outer electrodes of the at least one sensor part are located side by side on two diametrically opposite sides of the piezoelectric actuator.

13. The piezoelectric actuator according to claim 8, wherein
the inner electrodes of the at least one sensor part are located in the corner region and are each contacted there by outer electrodes.

14. The piezoelectric actuator according to claim 9, wherein
the inner electrodes of the at least one sensor part are located in the corner region and are each contacted there by outer electrodes.

15. The piezoelectric actuator according to claim 10, wherein
the inner electrodes of the at least one sensor part are located in the corner region and are each contacted there by outer electrodes.

16. The piezoelectric actuator according to claim 11, wherein
the inner electrodes of the at least one sensor part are located in the corner region and are each contacted there by outer electrodes.

17. The piezoelectric actuator according to claim 12, wherein
the inner electrodes of the at least one sensor part are located in the corner region and are each contacted there by outer electrodes.

18. The piezoelectric actuator according to claim 13, wherein
in the case of a plurality of sensor parts, the various inner electrodes are contacted in alternation by outer electrodes on different flanks of the corner region.

19. The piezoelectric actuator according to claim 14, wherein
in the case of a plurality of sensor parts, the various inner electrodes are contacted in alternation by outer electrodes on different flanks of the corner region.

20. The piezoelectric actuator according to claim 15, wherein
in the case of a plurality of sensor parts, the various inner electrodes are contacted in alternation by outer electrodes on different flanks of the corner region.

21. The piezoelectric actuator according to claim 16, wherein
in the case of a plurality of sensor parts, the various inner electrodes are contacted in alternation by outer electrodes on different flanks of the corner region.

22. The piezoelectric actuator according to claim 17, wherein
in the case of a plurality of sensor parts, the various inner electrodes are contacted in alternation by outer electrodes on different flanks of the corner region.

23. The piezoelectric actuator according to claim 8, wherein
a plurality of sensor elements connected in series are connected electrically parallel; and/or
a plurality of actuator elements connected in series are connected electrically parallel.

24. The piezoelectric actuator according to claim 10, wherein
a plurality of sensor elements connected in series are connected electrically parallel; and/or
a plurality of actuator elements connected in series are connected electrically parallel.

25. The piezoelectric actuator according to claim 11, wherein
a plurality of sensor elements connected in series are connected electrically parallel; and/or
a plurality of actuator elements connected in series are connected electrically parallel.

26. The piezoelectric actuator according to claim 13, wherein
a plurality of sensor elements connected in series are connected electrically parallel; and/or
a plurality of actuator elements connected in series are connected electrically parallel.

27. The piezoelectric actuator according to claim 18, wherein
a plurality of sensor elements connected in series are connected electrically parallel; and/or
a plurality of actuator elements connected in series are connected electrically parallel.
